(19) United States
(12) Patent Application Publication
(10) Pub. No.: US 2026/0233356 A1
(43) Pub. Date: Aug. 13, 2026

(54) SUBSTRATE POLISHING DEVICE AND POLISHING PAD

(71) Applicant: EBARA CORPORATION, Tokyo (JP)

(72) Inventor: Tetsuya TERADA, Tokyo (JP)

(73) Assignee: EBARA CORPORATION, Tokyo (JP)

(21) Appl. No.: 19/153,651

(22) PCT Filed: Feb. 6, 2024
(86) PCT No.: PCT/JP2024/003814

§ 371 Date: Aug. 5, 2025

(30) Foreign Application Priority Data
Feb. 7, 2023 (JP) 2023-016711

(51) Int. Cl. B24B 37/10; B24B 37/20

(52) U.S. Cl. CPC B24B 37/107; B24B 37/20

(57) ABSTRACT

A substrate polishing device includes a turntable having a first adhesive surface, and a polishing pad having a second adhesive surface adhesively fixed to the first adhesive surface. An adhesive region and a first separation assistance region are provided between the first adhesive surface and the second adhesive surface. The first adhesive surface and the second adhesive surface are adhered to each other in the adhesive region. An adhesive force acting between the first adhesive surface and the second adhesive surface in the first separation assistance region is smaller than an adhesive force acting between the first adhesive surface and the second adhesive surface in the adhesive region. The first separation assistance region is positioned on an outer circumferential portion of the polishing pad.

### TECHNICAL FIELD

The present invention relates to a substrate polishing device and a polishing pad. Priority is claimed on Japanese Patent Application No. 2023-016711 filed on Feb. 7, 2023, the content of which is incorporated herein by reference.

### BACKGROUND ART

Patent Document 1 discloses a polishing pad used in a substrate polishing device. The polishing pad has an adhesive portion for adhesively fixing the polishing pad to a rotating stage of the substrate polishing device. The adhesive portion is provided over the entire surface of the polishing pad.

### CITATION LIST

### Patent Document

Patent Document 1: Japanese Unexamined Patent Application, First Publication No. 2014-108498

### SUMMARY OF INVENTION

### Problem to be Solved by the Invention

Incidentally, work of replacing a polishing pad is frequently performed in a substrate polishing device. Particularly, when a polishing surface for polishing a substrate is provided on the polishing pad (see, for example, Patent Document 1), deterioration of the polishing surface (wear or adhesion of abrasive grains that becomes a defect source (such as scratches or particles)) occurs during continued polishing work. Then, for this reason, replacement of the polishing pad is frequently performed. However, when an adhesive portion is provided over the entire surface of the polishing pad such as, for example, the polishing pad described in Patent Document 1, it is difficult to separate the polishing pad from a rotating stage. Therefore, there have been cases in which replacement work of the polishing pad requires time and effort.

The present invention has been made in consideration of such circumstances, and an objective thereof is to provide a substrate polishing device and a polishing pad that allow easy replacement work of the polishing pad.

### Means to Solve the Problem

In order to solve the above-described problems, a substrate polishing device according to aspect 1 of the present invention includes a turntable having a first adhesive surface, and a polishing pad having a second adhesive surface adhesively fixed to the first adhesive surface, in which an adhesive region and a first separation assistance region are provided between the first adhesive surface and the second adhesive surface, the first adhesive surface and the second adhesive surface are adhered to each other in the adhesive region, an adhesive force acting between the first adhesive surface and the second adhesive surface in the first separation assistance region is smaller than an adhesive force acting between the first adhesive surface and the second adhesive surface in the adhesive region, and the first separation assistance region is positioned on an outer circumferential portion of the polishing pad.

Also, according to aspect 2 of the present invention, in the substrate polishing device of aspect 1, the adhesive region and the first separation assistance region may be formed on the second adhesive surface.

Also, according to aspect 3 of the present invention, in the substrate polishing device of aspect 2, the polishing pad may include a pad-shaped main body portion, and an adhesive portion which is provided to cover a part of a surface of the main body portion and exhibits an adhesive force, the adhesive region may be a portion of the polishing pad in which the adhesive portion is provided, and the first separation assistance region may be a portion of the polishing pad in which the adhesive portion is not provided.

Also, according to aspect 4 of the present invention, in the substrate polishing device of aspect 3, the polishing pad may include a pad-shaped main body portion, an adhesive portion which is provided to cover a surface of the main body portion and exhibits an adhesive force, and a low adhesive force portion which is provided to cover a part of a surface of the adhesive portion and exhibits an adhesive force lower than the adhesive force of the adhesive portion, the adhesive region may be a portion of the adhesive portion which is not covered with the low adhesive force portion, and the first separation assistance region may be a portion in which the low adhesive force portion is provided.

Also, according to aspect 5 of the present invention, in the substrate polishing device of aspect 2, the adhesive region and the first separation assistance region may be formed on the first adhesive surface.

Also, according to aspect 6 of the present invention, in the substrate polishing device of aspect 5, at least one recessed portion may be formed on a surface of the turntable, the adhesive region may be a portion of the turntable in which the recessed portion is not formed, and the first separation assistance region may be a portion of the turntable in which the recessed portion is formed.

Also, according to aspect 7 of the present invention, in the substrate polishing device of any one of aspects 1 to 6, the first separation assistance region may not be in contact with an outer circumferential edge of the polishing pad when viewed from an axial direction parallel to a central axis of the turntable.

Also, according to aspect 8 of the present invention, in the substrate polishing device of any one of aspects 1 to 7, a second separation assistance region may be further provided between the first adhesive surface and the second adhesive surface, an adhesive force acting between the first adhesive surface and the second adhesive surface in the second separation assistance region may be smaller than an adhesive force acting between the first adhesive surface and the second adhesive surface in the adhesive region, and when viewed from an axial direction parallel to a central axis of the turntable, the second separation assistance region may be positioned between the central axis and the first separation assistance region.

In order to solve the above-described problems, a polishing pad according to aspect 9 of the present invention is a polishing pad adhesively fixed to a turntable having a first adhesive surface, and includes a second adhesive surface adhesively fixed to the first adhesive surface, in which an adhesive region and a first separation assistance region which is positioned on an outer circumferential portion of the second adhesive surface are provided on the second adhesive surface, the adhesive region is a region adhered to the first adhesive surface, and the first separation assistance region is a region which is adhered to the first adhesive surface with a force lower than a force with which the adhesive region is adhered to the first adhesive surface, or a region which is not adhered to the first adhesive surface.

### Effects of the Invention

According to the above-described aspects of the present invention, it is possible to provide a substrate polishing device and a polishing pad that allow easy replacement work of the polishing pad.

### BRIEF DESCRIPTION OF DRAWINGS

FIG. 1 A view illustrating a substrate polishing device according to a first embodiment of the present invention.

FIG. 2 A view illustrating a second adhesive surface according to the first embodiment of the present invention.

FIG. 3 A cross-sectional view along line III-III illustrated in FIG. 2.

FIG. 4 A view illustrating a second adhesive surface according to a second embodiment of the present invention.

FIG. 5 A cross-sectional view along line V-V illustrated in FIG. 4.

FIG. 6 A view illustrating a first adhesive surface according to a third embodiment of the present invention.

FIG. 7 A cross-sectional view along line VI-VI illustrated in FIG. 6.

FIG. 8 A view illustrating a second adhesive surface according to a modified example of the present invention.

FIG. 9 A view illustrating a second adhesive surface according to another modified example of the present invention.

### DESCRIPTION OF EMBODIMENTS

### First Embodiment

Hereinafter, a substrate polishing device and a polishing pad according to a first embodiment will be described on the basis of the drawings.

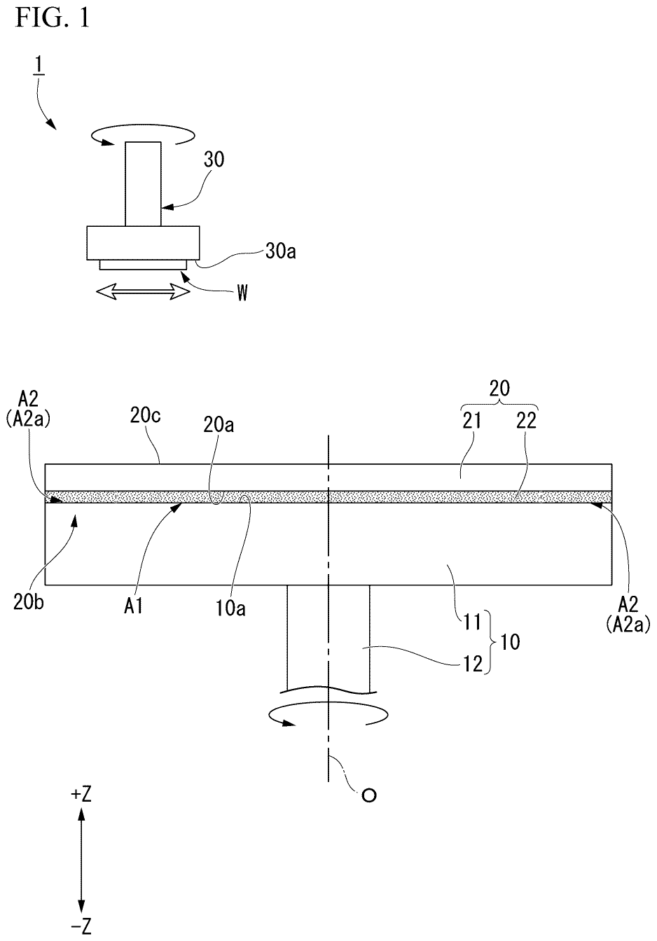

As illustrated in FIG. 1, a substrate polishing device 1 according to the present embodiment includes a turntable 10, a polishing pad 20, and a polishing head 30. The turntable 10 is configured to be rotatable around a central axis O of the turntable 10. The turntable 10 and the polishing pad 20 are adhesively fixed to each other. The polishing pad 20 has a polishing surface 20c for polishing a substrate W such as a silicon wafer. The polishing head 30 has a holding surface 30a for holding the substrate W. In the present embodiment, the substrate W is fixedly held on the holding surface 30a by being adsorbed onto the holding surface 30a.

### Definition of Directions

Here, in the present specification, a direction parallel to a central axis O of the turntable 10 is referred to as a Z direction or an axial direction Z. The axial direction Z is also a direction in which the turntable 10 and the polishing pad 20 face each other. A view from the axial direction Z is referred to as a plan view. A direction from the turntable 10 toward the polishing pad 20 in the axial direction Z is referred to as a +Z direction or an upward direction. A direction opposite to the +Z direction is referred to as a −Z direction or a downward direction. A cross section perpendicular to the axial direction Z is referred to as a cross section. A direction perpendicular to the central axis O of the turntable 10 when viewed from the axial direction Z is referred to as a radial direction. In the radial direction, a direction approaching the central axis O is referred to as a radially inward direction, and a direction away from the central axis O is referred to as a radially outward direction. A direction of revolving around the central axis O when viewed from the axial direction Z is referred to as a circumferential direction. The polishing surface 20c faces upward and the holding surface 30a faces downward.

The substrate polishing device 1 illustrated in FIG. 1 is a chemical mechanical polishing (CMP) device that polishes a surface of the substrate W to a flat surface using the polishing head 30. The polishing head 30 is configured, for example, to be capable of translational movement and rotational movement on the surface of the substrate W. While the turntable 10 rotates and the surface (lower surface) of the substrate W held on the holding surface 30a is in contact with the polishing surface 20c of the polishing pad 20, the polishing head 30 performs the translational movement and rotational movement. Thereby, the polishing surface 20c polishes the surface (lower surface) of the substrate W.

Further, types of the substrate polishing device 1 are not limited to chemical mechanical polishing devices and can be appropriately changed as long as the device can polish the substrate W. For example, the substrate polishing device 1 may be a bevel polishing device that polishes a bevel portion (outer circumferential portion) of the substrate W. Also, although detailed illustrations are omitted, the substrate polishing device 1 may also include a load port and an EFEM, a transfer machine, a cleaning unit, a drying unit, a control unit, and the like. The load port and the EFEM are ports through which the substrate W is transferred. The transfer machine transfers the substrate W. The cleaning unit cleans the substrate W. The drying unit dries the substrate W. The control unit comprehensively controls an operation of the substrate polishing device 1.

As illustrated in FIG. 1, the turntable 10 according to the present embodiment includes a stage portion 11 and a shaft portion 12. The shaft portion 12 is configured to be rotatable around the central axis O. The stage portion 11 and the shaft portion 12 are fixed to each other. Therefore, when the shaft portion 12 rotates, the stage portion 11 and the shaft portion 12 rotate integrally.

The turntable 10 has a first adhesive surface 10a. The first adhesive surface 10a is a surface that is adhesively fixed to a second adhesive surface 20a to be described later. In the present embodiment, the first adhesive surface 10a is an upper surface of the turntable 10 (stage portion 11). The first adhesive surface 10a according to the present embodiment has a circular shape in a plan view.

The polishing pad 20 according to the present embodiment includes a pad-shaped main body portion 21 and an adhesive portion 22. The main body portion 21 has the polishing surface 20c described above. The polishing surface 20c is an upper surface of the main body portion 21. The adhesive portion 22 is a portion that exhibits an adhesive force. Further, the term “adhesive force” in the present specification may also refer to a force that prevents separation between objects. That is, the “adhesive force” may also be an index related to a peel strength. A magnitude of such an “adhesive force” can be measured by, for example, a test conducted based on a standard such as JIS K 6854:1999, or the like. The adhesive portion 22 has a layered shape. The adhesive portion 22 is adhesively fixed to a lower surface of the main body portion 21.

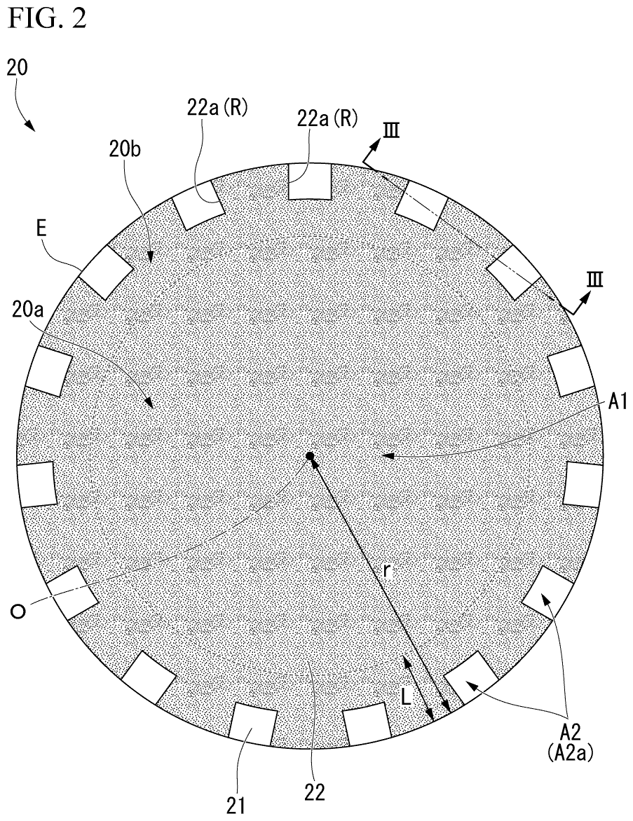

The polishing pad 20 has the second adhesive surface 20a. The second adhesive surface 20a is a surface that is adhesively fixed to the first adhesive surface 10a of the turntable 10. In the present embodiment, the second adhesive surface 20a is a lower surface of the polishing pad 20. As illustrated in FIG. 2, the second adhesive surface 20a according to the present embodiment has a circular shape in a plan view.

As illustrated in FIGS. 1 and 2, an adhesive region A1 and a separation assistance region A2 (first separation assistance region A2a) are provided between the first adhesive surface 10a and the second adhesive surface 20a. In the adhesive region A1, the first adhesive surface 10a and the second adhesive surface 20a are adhered to each other. An adhesive force acting between the first adhesive surface 10a and the second adhesive surface 20a in the separation assistance region A2 is smaller than an adhesive force acting between the first adhesive surface 10a and the second adhesive surface 20a in the adhesive region A1.

As illustrated in FIGS. 1 and 2, the separation assistance region A2 is positioned on an outer circumferential portion 20b of the polishing pad 20. Further, in the present specification, the term “outer circumferential portion 20b of the polishing pad 20” refers to a region that needs to be gripped by a jig, a robot hand, or the like when the polishing pad 20 is removed from the turntable 10 using the jig, the robot hand, or the like. For example, the outer circumferential portion 20b is an annular region positioned between an outer circumferential edge E of the polishing pad 20 and a point positioned a distance L radially inward from the outer circumferential edge E. The distance L satisfies, for example, r/20≤L≤r/3, where r is a radius of the polishing pad 20.

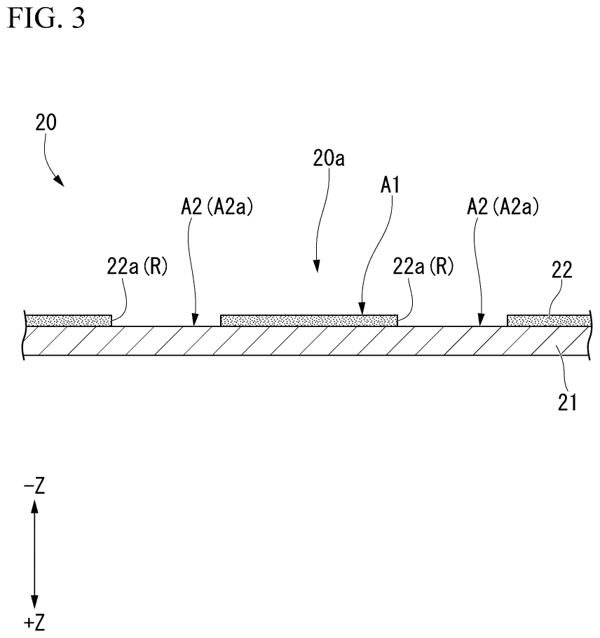

In the present embodiment, as illustrated in FIG. 2, the adhesive region A1 and the separation assistance region A2 are formed on the second adhesive surface 20a. Specifically, as illustrated in FIGS. 2 and 3, the adhesive portion 22 is provided to cover only a part of the surface (lower surface) of the main body portion 21. In other words, a part of the second adhesive surface 20a is a removed portion 22a from which the adhesive portion 22 has been removed. Then, a portion of the polishing pad 20 in which the adhesive portion 22 is provided is the adhesive region A1, and a portion (removed portion 22a) of the polishing pad 20 in which the adhesive portion 22 is not provided is the separation assistance region A2.

In the illustrated example, a plurality of removed portions 22a (separation assistance regions A2) are provided on the second adhesive surface 20a. The plurality of removed portions 22a are disposed at intervals over the entire circumference (entire outer circumferential portion 20b) of the polishing pad 20. However, disposition of the removed portions 22a is not limited to the illustrated example. The number, size, disposition interval, shape, and the like of the removed portions 22a can be appropriately changed. For example, the removed portion 22a may have a dot shape or the like. The plurality of removed portions 22a having different shapes from each other may be formed on the second adhesive surface 20a.

The removed portion 22a functions as an adhesive force reduction portion R that reduces the adhesive force acting between the first adhesive surface 10a and the second adhesive surface 20a. The separation assistance region A2 can also be defined as a portion in which the adhesive force reduction portion R is provided. Similarly, the adhesive region A1 can also be defined as a portion in which the adhesive force reduction portion R is not provided. Further, in the separation assistance region A2, the first adhesive surface 10a and the second adhesive surface 20a may be adhered to each other with a force lower than the force with which the first adhesive surface 10a and the second adhesive surface 20a are adhered to each other in the adhesive region A1. Alternatively, the first adhesive surface 10a and the second adhesive surface 20a may not be adhered to each other in the separation assistance region A2. In the separation assistance region A2 (adhesive force reduction portion R) according to the present embodiment, the first adhesive surface 10a and the second adhesive surface 20a are not adhered.

Next, an operation of the substrate polishing device 1 configured as above will be described.

Conventionally, a substrate polishing device in which an adhesive portion is provided over the entire surface of a polishing pad is known (see, for example, Patent Document 1). In such a substrate polishing device, work of replacing the polishing pad is performed frequently. Particularly, when a polishing surface for polishing a substrate is provided on the polishing pad (see, for example, Patent Document 1), deterioration of the polishing surface (wear or adhesion of abrasive grains that becomes a defect source (such as scratches or particles)) occurs during continued polishing work. Then, for this reason, replacement of the polishing pad is frequently performed. However, when the adhesive portion is provided over the entire surface of the polishing pad such as, for example, the polishing pad described in Patent Document 1, it is difficult to separate the polishing pad from a rotating stage. Therefore, there have been cases in which replacement work of the polishing pad requires time and effort.

In regard to this problem, in the substrate polishing device 1 of the present embodiment, the separation assistance region A2 (adhesive force reduction portion R) is provided in a portion positioned between the first adhesive surface 10a of the turntable 10 and the second adhesive surface 20a of the polishing pad 20, and positioned at the outer circumferential portion 20b of the polishing pad 20. According to this configuration, when a user performs replacement of the polishing pad 20, first, the first adhesive surface 10a and the second adhesive surface 20a can be easily separated in the separation assistance region A2. That is, a process of starting to separate the polishing pad 20 from the turntable 10 can be easily performed. After this process, the polishing pad 20 can be completely separated from the turntable 10 by, for example, gripping a part of the polishing pad 20 that has been separated in the separation assistance region A2 and peeling it off from the turntable 10. Alternatively, a member for separating the polishing pad 20 from the turntable 10 may be inserted into a gap generated between the polishing pad 20 and the turntable 10 in the separation assistance region A2. With the method as described above, replacement work of the polishing pad 20 can be easily performed.

As described above, the substrate polishing device 1 according to the present embodiment includes the turntable 10 having the first adhesive surface 10a, and the polishing pad 20 having the second adhesive surface 20a that is adhesively fixed to the first adhesive surface 10a, in which the adhesive region A1 and the separation assistance region A2 (first separation assistance region A2a) are provided between the first adhesive surface 10a and the second adhesive surface 20a. The separation assistance region A2 is positioned at the outer circumferential portion 20b of the polishing pad 20. Then, the adhesive force acting between the first adhesive surface 10a and the second adhesive surface 20a in the separation assistance region A2 is smaller than the adhesive force acting between the first adhesive surface 10a and the second adhesive surface 20a in the adhesive region A1. In other words, the adhesive force reduction portion R that reduces the adhesive force acting between the first adhesive surface 10a and the second adhesive surface 20a is provided in the separation assistance region A2.

With this configuration, the process of starting to separate the polishing pad 20 from the turntable 10 can be easily performed. Therefore, replacement work of the polishing pad 20 can be easily performed.

Also, the adhesive region A1 and the separation assistance region A2 are formed on the second adhesive surface 20a (polishing pad 20). In other words, the adhesive force reduction portion R is formed on the second adhesive surface 20a (polishing pad 20). With this configuration, the adhesive region A1 and the separation assistance region A2 can be provided between the first adhesive surface 10a of the turntable 10 and the second adhesive surface 20a of the polishing pad 20 without making significant modifications to the conventional turntable 10.

Also, the polishing pad 20 includes the pad-shaped main body portion 21 and the adhesive portion 22 that is provided to cover a part of the surface of the main body portion 21 and exhibit an adhesive force. Then, the adhesive region A1 is a portion of the polishing pad 20 in which the adhesive portion 22 is provided (a portion in which the adhesive force reduction portion R is not provided), and the separation assistance region A2 is a portion of the polishing pad 20 in which the adhesive portion 22 is not provided (a portion in which the adhesive force reduction portion R is provided). That is, the adhesive force reduction portion R is the removed portion 22a from which the adhesive portion 22 has been removed. With this configuration, the adhesive region A1 and the separation assistance region A2 can be easily formed on the second adhesive surface 20a.

### Second Embodiment

Next, a second embodiment will be described, but a basic configuration is the same as that of the first embodiment. Therefore, components which are the same are denoted by the same reference signs, description thereof will be omitted, and only different points will be described.

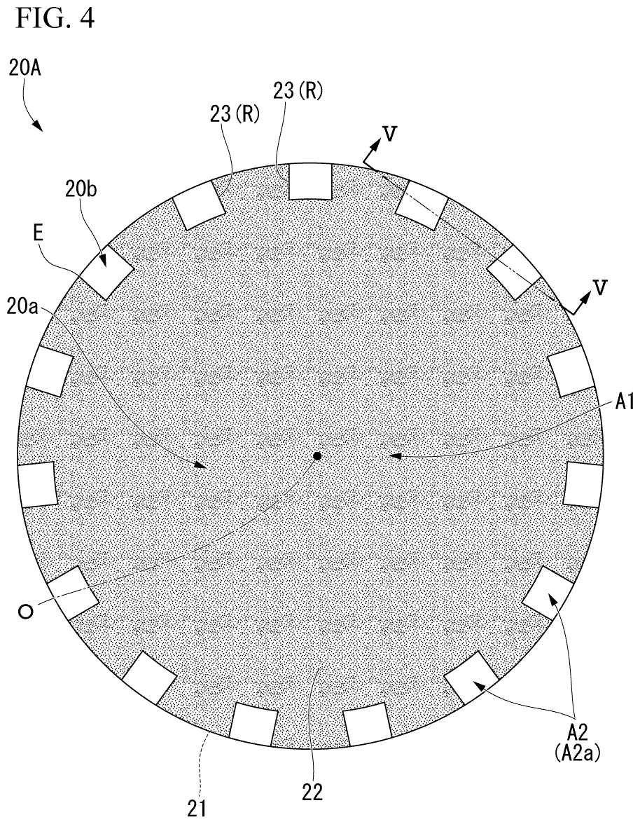

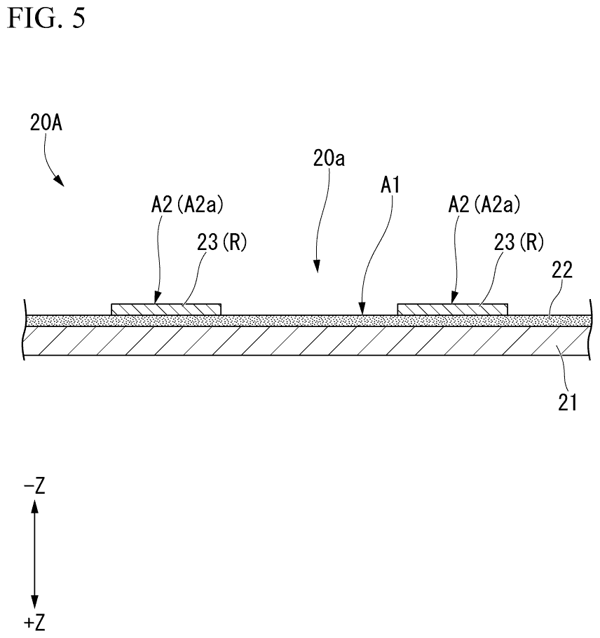

As illustrated in FIGS. 4 and 5, in a polishing pad 20A according to the present embodiment, an adhesive portion 22 is provided to cover the entire surface of a main body portion 21. That is, the removed portion 22a is not provided in the polishing pad 20A. The polishing pad 20A according to the present embodiment includes a low adhesive force portion 23 provided to cover a part of a surface of the adhesive portion 22, instead of the removed portion 22a. The low adhesive force portion 23 exhibits an adhesive force lower than that of the adhesive portion 22.

The low adhesive force portion 23 functions as an adhesive force reduction portion R. Thereby, similarly to the first embodiment, an adhesive region A1 and a separation assistance region A2 are formed on a second adhesive surface 20a. Specifically, a portion of the adhesive portion 22 that is not covered with the low adhesive force portion 23 is the adhesive region A1, and a portion thereof in which the low adhesive force portion 23 is provided is the separation assistance region A2. Further, in the present embodiment, as in the first embodiment, it is also possible to define the separation assistance region A2 as a portion in which the adhesive force reduction portion R is provided, and to define the adhesive region A1 as a portion in which the adhesive force reduction portion R is not provided.

In the illustrated example, a plurality of low adhesive force portions 23 (separation assistance regions A2) are provided on the second adhesive surface 20a. The plurality of low adhesive force portions 23 are disposed at intervals over the entire circumference (entire outer circumferential portion 20b) of the polishing pad 20. However, disposition of the low adhesive force portion 23 is not limited to the illustrated example. The number, size, disposition interval, shape, and the like of the low adhesive force portions 23 can be appropriately changed. For example, the low adhesive force portion 23 may have a dot shape or the like. The plurality of low adhesive force portions 23 having different shapes from each other may be provided on the second adhesive surface 20a.

As described above, the polishing pad 20A of the present embodiment includes the pad-shaped main body portion 21, the adhesive portion 22 provided to cover a surface of the main body portion 21 and exhibiting an adhesive force, and a low adhesive force portion 23 provided to cover a part of a surface of the adhesive portion 22 and having a lower adhesive force than the adhesive portion 22. Then, the adhesive region A1 is a portion of the adhesive portion 22 that is not covered with the low adhesive force portion 23, and the separation assistance region A2 is a portion in which the low adhesive force portion 23 is provided. That is, the adhesive force reduction portion R is the low adhesive force portion 23 that covers a part of the surface of the adhesive portion 22.

Even with this configuration, the adhesive region A1 and the separation assistance region A2 can be easily formed on the second adhesive surface 20a.

### Third Embodiment

Next, a third embodiment will be described, but a basic configuration is the same as that of the first embodiment. Therefore, components which are the same are denoted by the same reference signs, description thereof will be omitted, and only different points will be described.

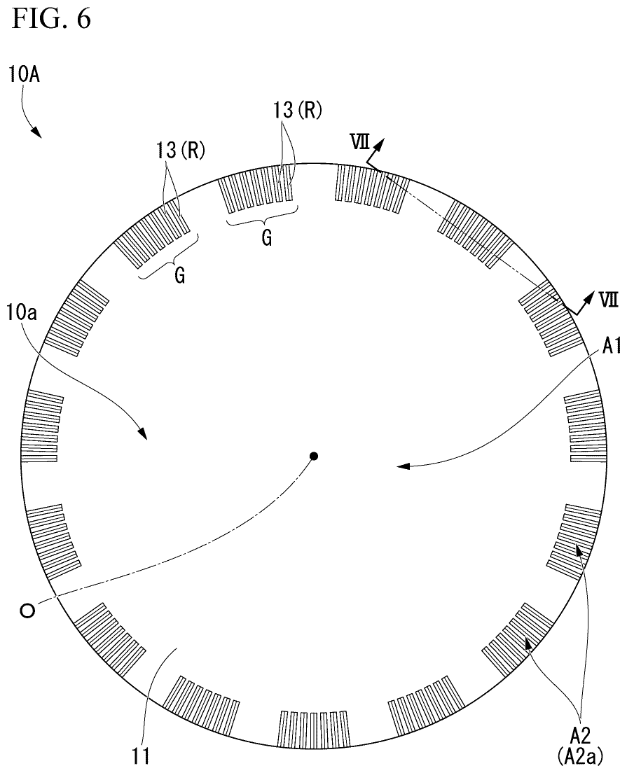

In the present embodiment, the adhesive force reduction portion R such as the removed portion 22a or the low adhesive force portion 23 is not provided in the polishing pad 20. On the other hand, in the present embodiment, as illustrated in FIG. 6, an adhesive force reduction portion R is formed on a first adhesive surface 10a of a turntable 10A.

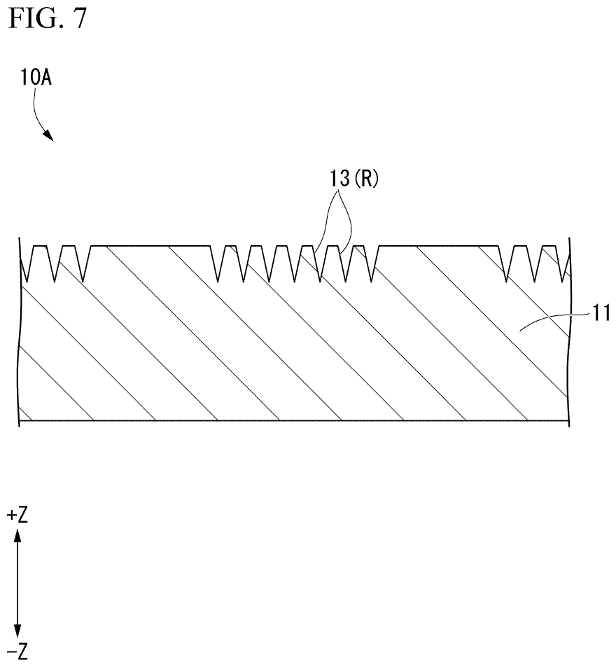

Specifically, the turntable 10A according to the present embodiment has a plurality of recessed portions 13 as illustrated in FIGS. 6 and 7. Each of the recessed portions 13 opens to a surface (first adhesive surface 10a) of the turntable 10A. Also, the recessed portion 13 is positioned on an outer circumferential portion of the turntable 10A.

In the present embodiment, the recessed portion 13 functions as the adhesive force reduction portion R. Thereby, an adhesive region A1 and a separation assistance region A2 are formed on the first adhesive surface 10a of the turntable 10A.

Specifically, a portion of the turntable 10A in which the recessed portion 13 is not formed is the adhesive region A1, and a portion of the turntable 10A in which the recessed portion 13 is formed is the separation assistance region A2. Further, in the present embodiment, as in the first embodiment, it is also possible to define the separation assistance region A2 as a portion in which the adhesive force reduction portion R is provided, and to define the adhesive region A1 as a portion in which the adhesive force reduction portion R is not provided.

In the illustrated example, the plurality of recessed portions 13 form a plurality of recessed portion groups G. In each of the recessed portion groups G, the plurality of recessed portions 13 are disposed close to each other. Then, the plurality of recessed portion groups G are disposed at intervals over the entire circumference of the turntable 10A. However, disposition of the recessed portions 13 is not limited to the illustrated example. The number, size, disposition interval, shape, and the like of the recessed portions 13 can be appropriately changed. For example, the recessed portion 13 may have a dot shape or the like. The plurality of recessed portions 13 having different shapes from each other may be provided on the first adhesive surface 10a.

As described above, in the substrate polishing device 1 according to the present embodiment, the adhesive region A1 and the separation assistance region A2 are formed on the first adhesive surface 10a (turntable 10A). In other words, the adhesive force reduction portion R is formed on the first adhesive surface 10a (turntable 10A). With this configuration, the adhesive region A1 and the separation assistance region A2 can be provided between the first adhesive surface 10a of the turntable 10A and the second adhesive surface 20a of the polishing pad 20 without making significant modifications to the conventional polishing pad 20.

Also, at least one recessed portion 13 is formed on the surface of the turntable 10A. Then, the adhesive region A1 is a portion of the turntable 10A in which the recessed portion 13 is not formed, and the separation assistance region A2 is a portion of the turntable 10A in which the recessed portion 13 is formed. That is, the adhesive force reduction portion R is the recessed portions 13 that open to the surface (first adhesive surface 10a) of the turntable 10A. With this configuration, the adhesive region A1 and the separation assistance region A2 can be easily formed on the first adhesive surface 10a.

Further, the technical scope of the present invention is not limited to the above-described embodiments, and various modifications can be made within a range not departing from the spirit of the present invention.

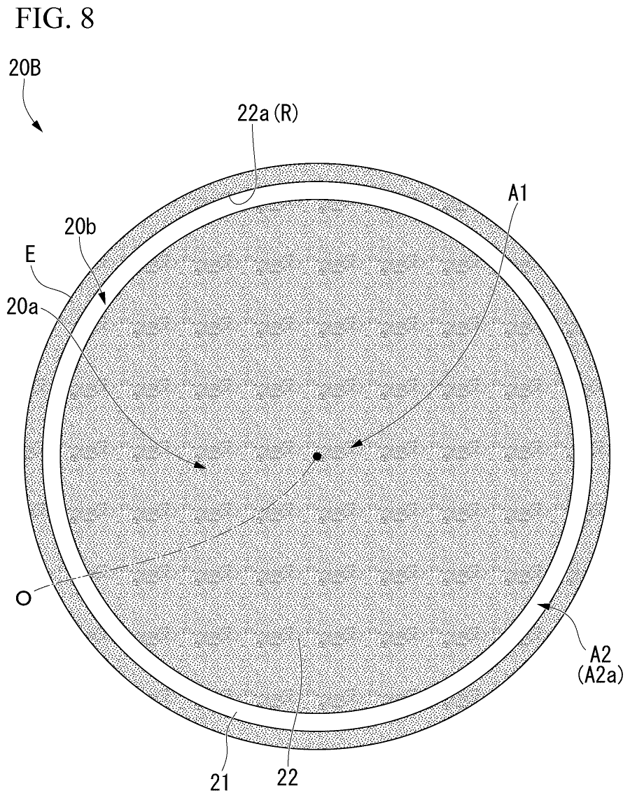

For example, as in the polishing pad 20B illustrated in FIG. 8, the separation assistance region A2 (adhesive force reduction portion R) does not have to be in contact with an outer circumferential edge E of the polishing pad 20B in a plan view. In this case, an inflow of a liquid such as water into the separation assistance region A2 can be suppressed. Further, the shape, the size, and the like of the separation assistance region A2 (adhesive force reduction portion R) illustrated in FIG. 8 are merely an example and can be changed as appropriate. For example, the separation assistance regions A2 (adhesive force reduction portion R) may be provided intermittently in the circumferential direction.

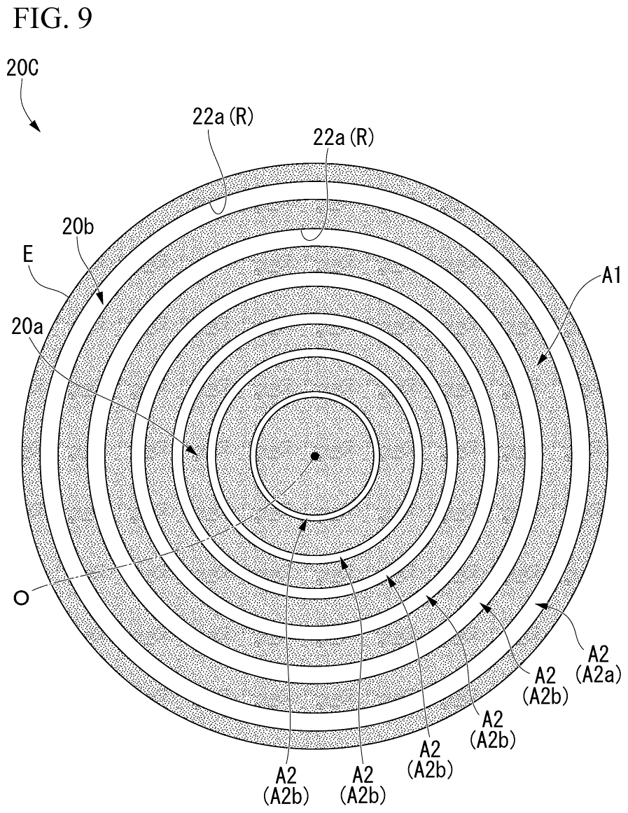

Also, as in the polishing pad 20C illustrated in FIG. 9, the separation assistance region A2 (second separation assistance region A2b) positioned between the central axis O and the first separation assistance region A2a in a plan view may be provided between the first adhesive surface 10a and the second adhesive surface 20a in addition to the separation assistance regions A2 (first separation assistance region A2a) positioned on the outer circumferential portion 20b of the polishing pad 20C. In the illustrated example, a plurality of annular separation assistance region A2a are disposed at intervals in the radial direction. According to this configuration, it becomes easier to separate the polishing pad 20 from the turntable 10. Further, the shapes, the sizes, and the like of the separation assistance regions A2a and A2b illustrated in FIG. 9 are merely examples and can be changed as appropriate. For example, the separation assistance regions A2a and A2b may be provided intermittently in the circumferential direction.

Also, in the above-described embodiment, the adhesive force reduction portion R has been formed on either the first adhesive surface 10a or the second adhesive surface 20a, but the adhesive force reduction portion R may be formed on both the first adhesive surface 10a and the second adhesive surface 20a. That is, it is sufficient that the adhesive force reduction portion R is formed on at least one of the first adhesive surface 10a and the second adhesive surface 20a.

Also, in the above-described embodiment, the polishing pad 20 have had the adhesive portion 22, but the turntable 10 may have the adhesive portion 22. Both the turntable 10 and the polishing pad 20 may each have the adhesive portion 22.

Also, the polishing pad 20 does not have to have the polishing surface 20c. In this case, a polishing surface, a polishing tape, or the like for polishing the substrate W may be provided on the polishing head 30, and a holding surface for holding the substrate W may be provided on the polishing pad 20.

In addition, the components in the above-described embodiments can be appropriately replaced with well-known components within a range not departing from the spirit of the present invention, and the embodiments and modified examples described above may be appropriately combined.

### REFERENCE SIGNS LIST

1 Substrate polishing device
10, 10A Turntable
10a First adhesive surface
13 Recessed portion
20, 20A, 20B, 20C Polishing pad
20a Second adhesive surface
20b Outer circumferential portion
21 Main body portion
22 Adhesive portion
23 Low adhesive force portion
A1 Adhesive region
A2a First separation assistance region
A2b Second separation assistance region
Z Axial direction

1. A substrate polishing device comprising:
a turntable having a first adhesive surface to which a second adhesive surface of a polishing pad is capable of being adhesively fixed, wherein
an adhesive region and a first separation assistance region are provided between the first adhesive surface and the second adhesive surface,
the first adhesive surface and the second adhesive surface are adhered to each other in the adhesive region,
an adhesive force acting between the first adhesive surface and the second adhesive surface in the first separation assistance region is smaller than an adhesive force acting between the first adhesive surface and the second adhesive surface in the adhesive region, and
the first separation assistance region is positioned on an outer circumferential portion of the polishing pad.

2. The substrate polishing device according to claim 1, further comprising the polishing pad, wherein
the adhesive region and the first separation assistance region are formed on the second adhesive surface.

3. The substrate polishing device according to claim 2, wherein
the polishing pad includes:
a pad-shaped main body portion; and
an adhesive portion which is provided to cover a part of a surface of the main body portion and exhibits an adhesive force,
the adhesive region is a portion of the polishing pad in which the adhesive portion is provided, and
the first separation assistance region is a portion of the polishing pad in which the adhesive portion is not provided.

4. The substrate polishing device according to claim 2, wherein
the polishing pad includes:
a pad-shaped main body portion;
an adhesive portion which is provided to cover a surface of the main body portion and exhibits an adhesive force; and
a low adhesive force portion which is provided to cover a part of a surface of the adhesive portion and exhibits an adhesive force lower than the adhesive force of the adhesive portion,
the adhesive region is a portion of the adhesive portion which is not covered with the low adhesive force portion, and
the first separation assistance region is a portion in which the low adhesive force portion is provided.

5. The substrate polishing device according to claim 1, wherein the adhesive region and the first separation assistance region are formed on the first adhesive surface.

6. The substrate polishing device according to claim 5, wherein
at least one recessed portion is formed on a surface of the turntable,
the adhesive region is a portion of the turntable in which the recessed portion is not formed, and
the first separation assistance region is a portion of the turntable in which the recessed portion is formed.

7. The substrate polishing device according to claim 1, wherein the first separation assistance region is not in contact with an outer circumferential edge of the polishing pad when viewed from an axial direction parallel to a central axis of the turntable.

8. The substrate polishing device according to claim 1, wherein
a second separation assistance region is further provided between the first adhesive surface and the second adhesive surface,
an adhesive force acting between the first adhesive surface and the second adhesive surface in the second separation assistance region is smaller than an adhesive force acting between the first adhesive surface and the second adhesive surface in the adhesive region, and
when viewed from an axial direction parallel to a central axis of the turntable, the second separation assistance region is positioned between the central axis and the first separation assistance region.

9. A polishing pad adhesively fixed to a turntable having a first adhesive surface, comprising a second adhesive surface adhesively fixed to the first adhesive surface, wherein
an adhesive region and a first separation assistance region which is positioned on an outer circumferential portion of the second adhesive surface are provided on the second adhesive surface,
the adhesive region is a region adhered to the first adhesive surface, and
the first separation assistance region is a region which is adhered to the first adhesive surface with a force lower than a force with which the adhesive region is adhered to the first adhesive surface, or a region which is not adhered to the first adhesive surface.
